(19) United States
(12) Patent Application Publication
(10) Pub. No.: US 2002/0182864 A1
(43) Pub. Date: Dec. 5, 2002

(54) Etching process

(75) Inventor: Gow-Wei Sun, Taipei Hsien (TW)

Correspondence Address: JC Patents, Inc, 4 Venture, Suite 250, Irvine, CA, 92618, US

(73) Assignee: United Microelectronics Corp., Hsinchu (TW)

(21) Appl. No.: 09/888,846

(22) Filed: Jun. 25, 2001

(30) Foreign Application Priority Data
Jun. 1, 2001 (TW) 90113305

(51) Int. Cl. H01L 21/302; H01L 21/461

(52) U.S. Cl. 438/689

(57) ABSTRACT

An etching process. The etching process comprises the steps of providing a substrate having an isolation region and a first conductive region and a second conductive region formed thereon. The second conductive region is higher than the first conductive region. An etching stop layer is formed over the substrate. A dielectric layer is formed on the etching stop layer. An etching process is performed with a mixture gas including CH₂F₂, C₅F₈, CO, O₂ and Ar to form a first opening and a second opening in the dielectric layer, wherein the first opening exposes a portion of the first conductive region and a portion of the isolation region and the second opening exposes a portion of the etching stop layer over the second conductive region.

### CROSS-REFERENCE TO RELATED APPLICATION

This application claims the priority benefit of Taiwan application serial no. 90113305, filed Jun. 1, 2001.

### BACKGROUND OF THE INVENTION

1. Field of Invention

The present invention relates to an etching process. More particularly, the present invention relates to an etching method which can improve the etching resistance of an etching stop layer.

2. Description of Related Art

In the semiconductor manufacturing process such as dual damascene process, self-aligned contact process, an etching stop layer has been widely used. While the depth of the trench or the via reaches the customer-designed, the etching process can be well controlled to stop etching because of the role played by the stop layer in the etching process.

Conventionally, in the process for forming metal interconnects, a trench or a via is formed in the dielectric layer by using the silicon nitride as an etching stop layer and referring to the different etching rate between the silicon oxide and the silicon nitride. Besides, the mixture gas including C₅F₈, CO, O₂, Ar is used as an etching gas to etch silicon oxide until the silicon nitride is exposed.

However, by using the mixture gas including C₅F₈, CO, O₂, Ar as the etching gas, the etching rate difference between silicon nitride and the silicon oxide is not high enough. If the trench or the via is not aligned to the conductive region and partially located over the isolation region, it is possible that the silicon nitride is penetrated through and the isolation structure is destroyed during the etching process because of the slightly different etching rate between the silicon nitride and the silicon oxide. Then, the leakage happens around the destroyed portion of the isolation region.

Moreover, the mixture gas including C₅F₈, CO, O₂, Ar used as the etching gas will lead to the small etching ratio of the silicon oxide to the silicon nitride, so that when the trenches or the vias with different depth are formed, or the density of the trenches or vias are not uniform, the loading effect happens. The loading effect is that the etching rate on etching the target film to form relatively wide trench or via is fast. On the other hand, the etching rate on etching the target film to form relatively narrow trench or via is slow. Similarly, the etching rate on etching the target film to form the trench or via with relatively high density is slow, and the etching rate on etching the target film to form the trench or via with relatively low density is fast. Because the etching rate difference between the silicon nitride and the silicon oxide is small, the silicon nitride in the trench or the via with relatively large wideness is exposed before the depth of the trench or the via with relatively small wideness reaches the customer-designed requirement. While the depth of the trench or via reaches with the relatively small wideness reaches the customer-designed requirement, the silicon nitride on the bottom of the trench or the via has already been penetrated through by the etchant. Therefore, after the trench or the via is filled by the conductive layer, the leakage happens.

### SUMMARY OF THE INVENTION

The invention provides an etching process. The etching process comprises the steps of providing a substrate having an isolation region and a first conductive region and a second conductive region formed thereon. The second conductive region is higher than the first conductive region. An etching stop layer is formed over the substrate. A dielectric layer is formed on the etching stop layer. An etching process is performed with a mixture gas including CH₂F₂, C₅F₈, CO, O₂ and Ar to form a first opening and a second opening in the dielectric layer, wherein the first opening exposes a portion of the first conductive region and a portion of the isolation region and the second opening exposes a portion of the etching stop layer over the second conductive region.

The present invention provides an etching process. The etching process comprises steps of providing a substrate having a conductive layer formed thereon. An etching stop layer is formed over the substrate. A dielectric layer is formed on the etching stop layer. An etching process with a mixture gas including CH₂F₂, C₅F₈, CO, O₂ and Ar is performed to form a first opening and a second opening in the dielectric layer, wherein the first and the second openings expose a portion of the etching stop layer and the first opening is wider than the second opening.

In the present invention, the mixture gas including CH₂F₂, C₅F₈, CO, O₂ and Ar can improve the etching resistance of the etching stop layer to prevent the etching stop layer from being etched through.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is schematic, cross-sectional view of an opening formed by an etching process in the first preferred embodiment according to the invention; and

FIG. 2 is schematic, cross-sectional view of openings with different wideness formed by an etching process in the second preferred embodiment according to the invention.

### DESCRIPTION OF THE PREFERRED EMBODIMENTS

First Embodiment

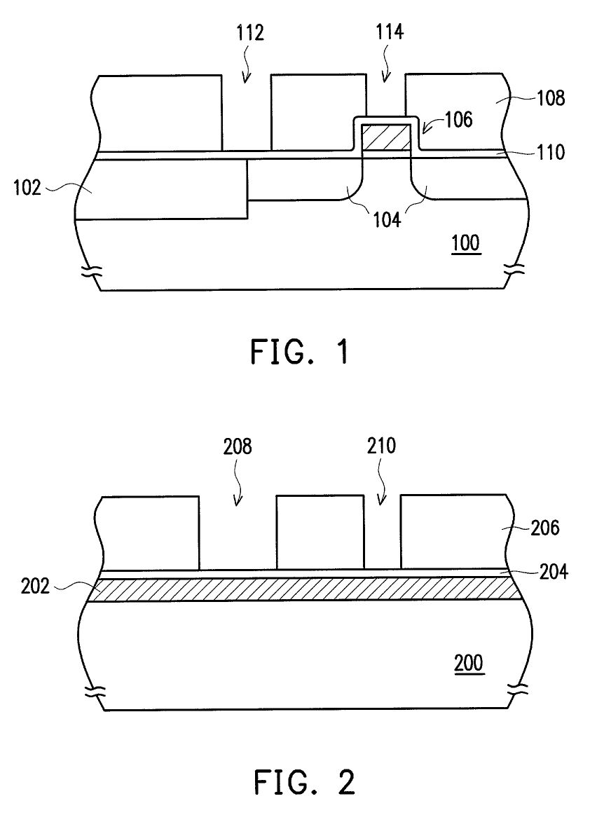

FIG. 1 is schematic, cross-sectional view of an opening formed by an etching process in the first preferred embodiment according to the invention.

As shown in FIG. 1, a substrate 100 having a shallow trench isolation region 102, a gate electrode structure 106 and a source/drain region 104 are formed thereon is provided. An etching stop layer 110 is formed over the substrate 100. The etching stop layer 110 can be formed from silicon nitride, silicon oxy nitride or silicon carbide by chemical vapor deposition (CVD), for example. The thickness of the etching stop layer 110 is about 150-2000 angstroms. A dielectric layer 108 is formed on the etching stop layer 110. The dielectric layer 108 can be formed from silicon oxide, fluorinated silica glass (FSG) or undoped silica glass (USG) by CVD, for example.

An etching process is performed to form a first opening 112 and a second opening 114 in the dielectric layer 108. The first opening 112 and the second opening 114 expose a portion of the etching stop layer 110. The opening 112 can be a via or a trench, for example. The gas used in the etching process is a mixture gas including CH₂F₂, C₅F₈, CO, O₂ and Ar. The flow rate of CH₂F₂ is about 1-20 sccm, the flow rate of C₅F₈ is about 5-20 sccm, the flow rate of CO is about 50-400 sccm, the flow rate of O₂ is about 2-20 sccm and the flow rate of Ar is about 150-800 sccm, for example.

During the mixture gas provided by the present invention is used to etching the dielectric layer 108 to form the first opening 112 misaligning to the source/drain region 104, the mixture gas an improve the etching resistance of the etching stop layer 110. Hence, the etching stop layer being etched through in the etching process under the misalignment situation can be avoided and the shallow trench isolation being exposed by the misaligned opening or being destroyed by the echant can be avoided. Therefore, the leakage phenomenon can be avoided.

Moreover, during using the mixture gas provided by the invention to etch the dielectric layer 108 in order to form openings with different depth, such as the first opening and the second opening in FIG. 1, the etching process would be performed until the first opening 112 completely formed even after the second opening 114 has been already formed. The mixture gas provided by the invention can improve the etching resistance of the etching stop layer, so that the portion of the etching stop layer exposed by the second opening 114 can be avoided from being etching through during the formation of the first opening 112.

Second Embodiment

FIG. 2 is schematic, cross-sectional view of openings with different wideness formed by an etching process in the second preferred embodiment according to the invention.

As shown in FIG. 2, a substrate 200 having a conductive layer 202 formed thereon is provided. The conductive layer 202 can be a gate, a source/drain or a metal interconnects. An etching stop layer 204 is formed over the conductive layer 202. The etching stop layer 204 can be formed from silicon nitride, silicon oxy nitride or silicon carbide by CVD, for example. The thickness of the etching stop layer 204 is about 150-2000 angstroms, for example. A dielectric layer 206 is formed on the etching stop layer 204. The dielectric layer 206 can be formed from silicon oxide, fluorinated silica glass (FSG) or undoped silica glass (USG) by CVD, for example.

An etching process is performed to form a first opening 208 and a second opening 210 in the dielectric layer 206. The first opening 208 and the second opening 210 respectively expose a portion of the etching stop layer 204. The first opening 208 is wider than the second opening 210. The first opening 208 and the second opening 210 can be vias or trenches, for example. The gas used in the etching process is a mixture gas including CH₂F₂, C₅F₈, CO, O₂ and Ar. The flow rate of CH₂F₂ is about 1-20 sccm, the flow rate of C₅F₈ is about 5-20 sccm, the flow rate of CO is about 50-400 sccm, the flow rate of O₂ is about 2-20 sccm and the flow rate of Ar is about 150-800 sccm, for example.

Since the first opening 208 is wider than the second opening 210, the etching rate for etching the dielectric material in the first opening 208 is faster than that for etching the dielectric material in the second opening 210. Therefore, a portion of the etching stop layer 204 on the bottom of the first opening 2008 is exposed before a portion of the etching stop layer 204 on the bottom of the second opening 210 is exposed. Hence, the etching process is performed until the portion of the etching stop layer 204 on the bottom of the second opening 210 is exposed. During the mixture gas provided by the present invention is used to etching the dielectric layer to form the first opening 208 and the second opening 210, the mixture gas an improve the etching resistance of the etching stop layer 204 exposed by the first opening 208 to avoid the etching stop layer 204 from being etched through while the dielectric material is still removed to form the second opening 210. Hence, the undesired conduction between the upper conductive layer and underlayer can be avoided and the leakage phenomenon can be avoided.

In the present invention, the mixture gas including CH₂F₂, C₅F₈, CO, O₂ and Ar can improve the etching resistance of the etching stop layer to prevent the etching stop layer from being etched through. Therefore, it is believed that the present invention can be used in the method for manufacturing a dual damascene structure, since there are two etching stop layer formed during the dual damascene process in order to respectively form a via and a trench. Specially, in the method for manufacturing a copper-metal-dual damascene structure, because of the high diffusion ability of the metal copper, the etching stop layer used in the formation of the via and the trench must possess sufficient etching resistance. Therefore, the metal copper can be well blocked and won't diffuse into the dielectric layer.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. An etching process, comprising the steps of:
providing a substrate having an isolation region and a first conductive region and a second conductive region formed thereon, wherein the second conductive region is higher than the first conductive region;
forming an etching stop layer over the substrate;
forming a dielectric layer on the etching stop layer; and
performing an etching process with a mixture gas including CH₂F₂, C₅F₈, CO, O₂ and Ar to form a first opening and a second opening in the dielectric layer, wherein the first opening exposes a portion of the first conductive region and a portion of the isolation region and the second opening exposes a portion of the etching stop layer over the second conductive region.

2. The etching process of claim 1, wherein a flow rate of CH₂F₂ is about 1-20 sccm.

3. The etching process of claim 1, wherein a flow rate of C₅F₈ is about 5-20 sccm.

4. The etching process of claim 1, wherein a flow rate of CO is about 50-400 sccm.

5. The etching process of claim 1, wherein a flow rate of O₂ is about 2-20 sccm.

6. The etching process of claim 1, wherein a flow rate of Ar is about 150-800 sccm.

7. The etching process of claim 1, wherein an etching rate of the etching stop layer is slower than an etching rate of the dielectric layer.

8. The etching process of claim 1, wherein the etching stop layer is formed from one of silicon nitride, silicon oxy nitride and silicon carbide.

9. The etching process of claim 1, wherein the dielectric layer is formed from one of silicon oxide, fluorinated silica glass (FSG) and undoped silica glass (USG).

10. An etching process, comprising the steps of:
providing a substrate having a conductive layer formed thereon;
forming an etching stop layer over the substrate;
forming a dielectric layer on the etching stop layer; and
performing an etching process with a mixture gas including CH₂F₂, C₅F₈, CO, O₂ and Ar to form a first opening and a second opening in the dielectric layer, wherein the first and the second openings expose a portion of the etching stop layer and the first opening is wider than the second opening.

11. The etching process of claim 10, wherein a flow rate of CH₂F₂ is about 1-20 sccm.

12. The etching process of claim 10, wherein a flow rate of C₅F₈ is about 5-20 sccm.

13. The etching process of claim 10, wherein a flow rate of CO is about 50-400 sccm.

14. The etching process of claim 10, wherein a flow rate of O₂ is about 2-20 sccm.

15. The etching process of claim 10, wherein a flow rate of Ar is about 150-800 sccm.

16. The etching process of claim 10, wherein an etching rate of the etching stop layer is slower than an etching rate of the dielectric layer.

17. The etching process of claim 10, wherein the etching stop layer is formed from one of silicon nitride, silicon oxy nitride and silicon carbide.

18. The etching process of claim 10, wherein the dielectric layer is formed from one of silicon oxide, fluorinated silica glass (FSG) and undoped silica glass (USG).
